(19) United States
(12) Patent Application Publication
(10) Pub. No.: US 2010/0314632 A1
(43) Pub. Date: Dec. 16, 2010

(54) INTEGRATED CIRCUIT PACKAGE

(76) Inventor: Toshinobu Hatano, Kyoto (JP)

Correspondence Address: MCDERMOTT WILL & EMERY LLP, 600 13TH STREET, NW, WASHINGTON, DC, 20005-3096, US

(21) Appl. No.: 12/864,640

(22) PCT Filed: Dec. 17, 2008
(86) PCT No.: PCT/JP2008/003823

§ 371 Date: Jul. 26, 2010

(30) Foreign Application Priority Data
Mar. 11, 2008 (JP) 2008-060867

(51) Int. Cl. H01L 33/58; H01L 33/48; H01L 33/62

(52) U.S. Cl. 257/84; 257/E33.077; 257/E33.067

(57) ABSTRACT

A portion of a package in which a silicon chip (101) is incorporated or a portion of an outer periphery of the package includes a light emitting unit (103) and a light receiving unit (102), the package has such a basic shape that its outer periphery includes a convex portion and a concave portion, and the light emitting unit (103) and the light receiving unit (102) are mounted on the convex portion and the concave portion. The convex portion can physically be bonded to a concave portion of another package, and the concave portion can physically be bonded to a convex portion of another package. At that time, light emitting units (103) and light receiving units (102) of the two integrated circuit packages are bonded to each other such that they are opposed to each other.

### TECHNICAL FIELD

The present invention relates to a package structure of an integrated circuit that converts a light signal to an electric signal, or converts an electric signal to a light signal.

### BACKGROUND ART

According to a conventional technique, a first interface portion for an electric signal and a second interface portion for a light signal are provided on a semiconductor chip so that both signal transmission by an electric signal and signal transmission by a light signal can easily be realized. An optical waveguide array is provided between a plurality of semiconductor chips mounted on a printed-circuit board (see patent document 1).

Various conventional techniques concerning optical wiring between semiconductor chips are introduced in the patent document 1. That is, the following schemes are known: an optical connector connecting scheme, a free space transmitting scheme, an optical waveguide embedding scheme, an active interposer scheme, and a surface mount scheme (see non-patent documents 1 and 2).

As conventional optical package structures, there are a structure in which an optical package includes a mount body having V-grooves and terminal pins, and a lid for covering an upper surface of the mount body, an optical integrated circuit is mounted in the mount body, optical fibers are placed in the V-grooves and then, the mount body and the lid are integrally adhered to each other by an adhesive and the optical fibers are fixed in the V-grooves (see patent document 2), and a structure in which holes are formed in a bottom surface of a mount body, an optical integrated circuit is placed on the bottom surface of the mount body, optical fibers are inserted into the holes and are fixed thereto by an adhesive (see patent document 3). In addition to these structures, there are various optical transmission approaches (see patent documents 4 and 5 for example).

### Citation List

### Patent Documents

PATENT DOCUMENT 1: Japanese Patent Publication No. 2006-201500

PATENT DOCUMENT 2: Japanese Utility Model Publication No. S61-176512

PATENT DOCUMENT 3: Japanese Utility Model Publication No. S61-144658

PATENT DOCUMENT 4: Japanese Patent Publication No. 2004-31872

PATENT DOCUMENT 5: Japanese Patent Publication No. S62-123412

### Non-Patent Documents

NON-PATENT DOCUMENT 1: Nikkei Electronics “Encounter with optical wiring” Dec. 3, 2001, pages 109 to 127

NON-PATENT DOCUMENT 2: Y. ANDO: “Trends in optical interconnection technologies and their impact on next-generation equipment packaging”, NTT R&D, vol. 48, no. 3, pp. 271 to 280 (1999)

### SUMMARY OF THE INVENTION

### Technical Problem

According to the conventional mounting approach utilizing an optical transmission channel on a system board, a parts cost, an implementation cost, an optical transmission channel cost and light-electricity converting module cost bulk up, and a situation that “optical system is expensive and mounting operation thereof is troublesome” occurs.

It is an object of the present invention to provide an inexpensive and high-usability integrated circuit package utilizing optical connection.

### Solution to the Problem

The present invention has been accomplished in view of the above problem, and the invention provides an integrated circuit package on which a semiconductor integrated circuit is mounted, wherein a portion of the package or a portion of an outer periphery thereof includes a light emitting unit and a light receiving unit, the package has such a basic shape that its outer periphery includes a convex portion and a concave portion, and the light emitting unit and the light receiving unit are mounted on the convex portion and the concave portion. The convex portion can physically be bonded to a concave portion of another package, the concave portion can physically be bonded to a convex portion of another package and at that time, light emitting units and light receiving units of the two integrated circuit packages are bonded to each other such that they are opposed to each other.

An electronic equipment on which a plurality of electronic components employing the integrated circuit package of the invention are mounted can carry out a signal transmission between a first electronic component and a second electronic component included in the plurality of electronic components using an optical bonded portion incorporated and mounted in a physical bonded surfaces of the convex portion and the concave portion as an interface.

In addition to the light emitting unit and the light receiving unit incorporated in the physical bonded portion between the convex portion and the concave portion, the electronic equipment on which a plurality of electronic components employing the integrated circuit packages are mounted has electronic power source/GND electrodes, and has such a structure that the electric power source/GND electrodes are connected between the plurality of integrated circuit packages in a cascade manner in some cases.

The integrated circuit packages of the invention can electrically be connected only through the power source/GND.

In the integrated circuit package of the invention, when an upper surface has a tetragonal shape, the convex and concave portions can be connected in the four directions of its outer periphery.

In the integrated circuit package of the invention, when an upper surface has a tetragonal shape, light emitting/receiving units are provided on the upper surface and a lower surface, and when a plurality of integrated circuit packages are piled on one another, the convex and concave portions can be connected in four mounting directions at locations where the light emitting/receiving units are opposed to each other.

The integrated circuit package of the invention may employ a structure in which a plurality of signal electrodes are arranged on a back surface of the package for realizing conventional terminal transmission of an electric signal.

In the integrated circuit package of the invention, the light emitting unit and the light receiving unit include a light receiving element, a driver thereof, a light emitting element, a receiver thereof, and an optical part for changing an optical path.

### Advantages of the Invention

According to the invention, concrete optical transmission channels between integrated circuit packages are eliminated in an electronic equipment, thereby realizing a high quality very high speed signal connection with small loss. It is possible to largely suppress a cost increase, and a plurality of semiconductor integrated circuits can be connected to each other with low power and with minimum mounting area. Therefore, it is possible to realize a new high speed optical communication, and to secure compatibility of conventional metal communication standard.

### BRIEF DESCRIPTION OF THE DRAWINGS

FIG. 1 is a schematic sectional view showing a basic physical shape of an integrated circuit package according to a first embodiment of the present invention;

FIG. 2 is a schematic plan view of an apparatus formed by connecting three integrated circuit packages shown in FIG. 1;

FIG. 3 is an enlarged sectional view taken along the line in FIG. 2;

FIG. 4 is a schematic sectional view showing a basic physical shape of an integrated circuit package according to a second embodiment of the invention;

FIG. 5 is a schematic sectional view of an apparatus formed by connecting three integrated circuit packages shown in FIG. 4;

FIG. 6 is a plan view showing a system connection of custom packages as a development of the first embodiment of the invention;

FIG. 7 is a plan view showing a system connection of a custom package as a development of the first embodiment of the invention;

FIG. 8 is a plan view showing a system connection of general packages as a development of the first embodiment of the invention;

FIG. 9 is a perspective view showing a physical connection of block type optical packages as a development of the first embodiment of the invention;

FIG. 10 is a perspective view showing approach arrangement of optical packages as a development of the first embodiment of the invention;

FIG. 11 is a schematic plan view showing a basic physical shape of an integrated circuit package that simultaneously realizes transmission of a present electric signal as a development of the first embodiment of the invention;

FIG. 12 is a sectional view taken along the line XII-XII in FIG. 11;

FIG. 13 is a sectional view taken along the line XIII-XIII in FIG. 11; and

FIG. 14 is a diagram of mounted optical transmission function parts in the integrated circuit package of the invention.

### DESCRIPTION OF EMBODIMENTS

Embodiments of the present invention will be described with reference to the drawings.

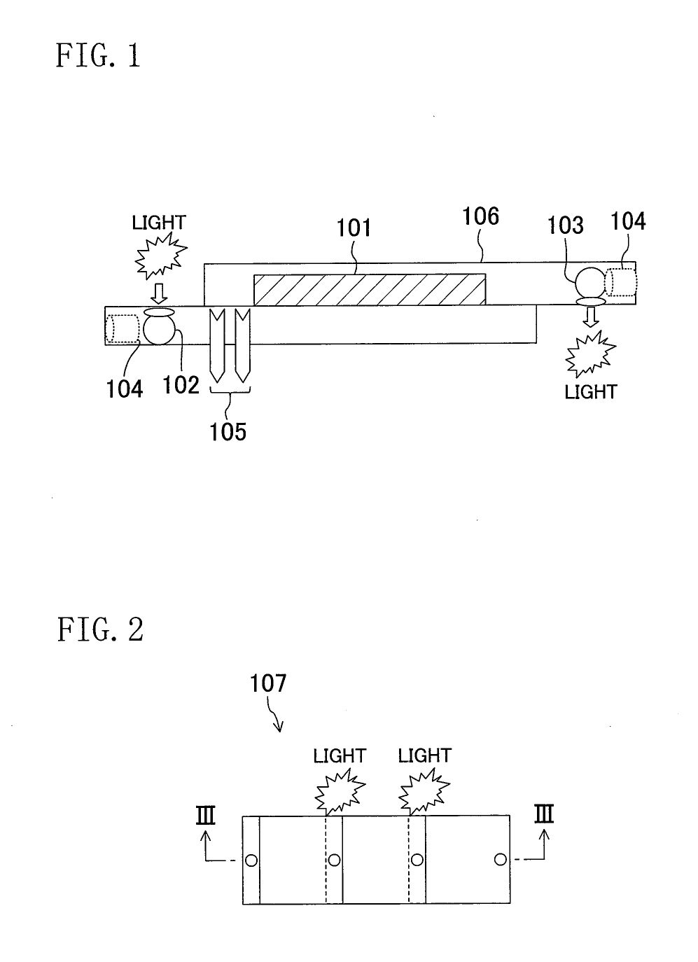

FIGS. 1 to 3 schematically show integrated circuit packages that realize optical transmission as a first embodiment.

In FIG. 1, a symbol 101 represents a silicon chip on which a semiconductor integrated circuit is mounted. A symbol 102 represents a light receiving unit mounted in a periphery of a package. A symbol 103 represents a light emitting unit also mounted in a periphery of the package. A symbol 104 represents a light socket that introduces light of an optical fiber into the light receiving unit or light of the light emitting unit into an optical fiber. A symbol 105 represents a power source/GND portion that is electrically connected to an electric member in the package and that can be electrically connected to a member outside of the package. A symbol 106 represents a mount body or a lid that makes a function element as one package.

In FIG. 2, a symbol 107 represents an apparatus having three optical packages (integrated circuit packages) having the same physical shapes and shown in FIG. 1. The three optical packages are connected to one another.

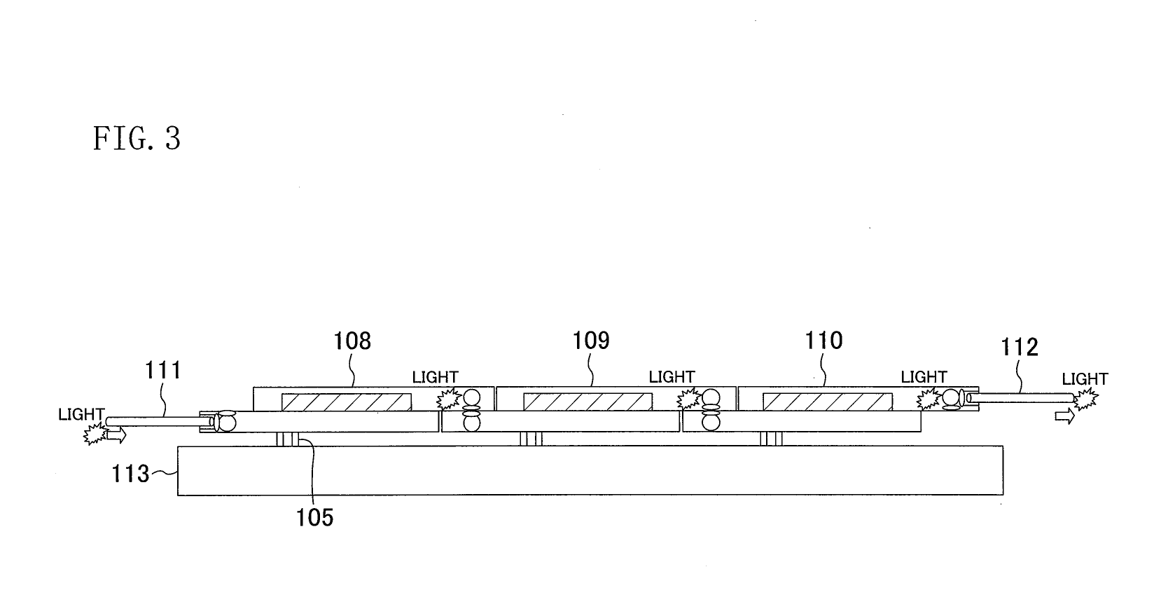

FIG. 3 is a sectional view of the apparatus. In FIG. 3, symbols 108, 109 and 110 represent optical packages having the same physical shapes and realizing different functions. For example, the first package 108 functions as an LSI of an A/D converter and a sensor, the second package 109 functions as an image processing LSI, and the third package 110 functions as an LSI of a general-purpose memory. Symbols 111 and 112 represent optical fibers that are mounted on light sockets of the packages 108 and 110 and that realize optical transmission with respect to another package located away from the packages 108 and 110. A symbol 113 represents a system board (mother board) that is electrically connected to the power source/GND portion 105 of the optical packages 108, 109 and 110.

The plurality of mounted optical packages having the basic configuration shown in FIG. 1 are spatially bonded to one another at locations where the light receiving units 102 and the light emitting units 103 are opposed to each other. With this, optical transmission is realized between a plurality of LSIs utilizing a light signal that can be recognized as a multilevel signal level in which light pulse or level by extremely faint light quantity is taken into account. The basic shape of an outer periphery of the package is symmetric with respect to an origin point where barycenters of physical size and shape are located. With this, optical connection utilizing the shortest free space of a plurality of LSIs is carried out.

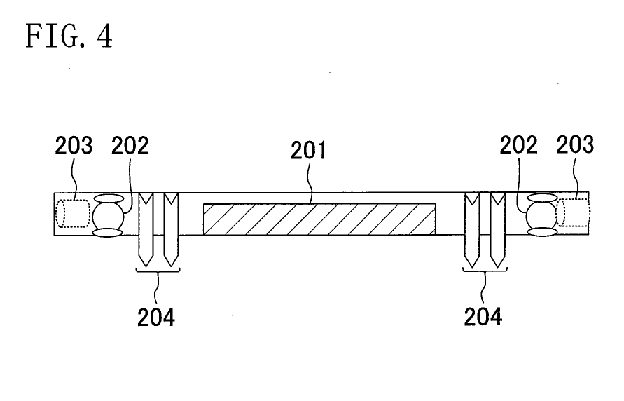

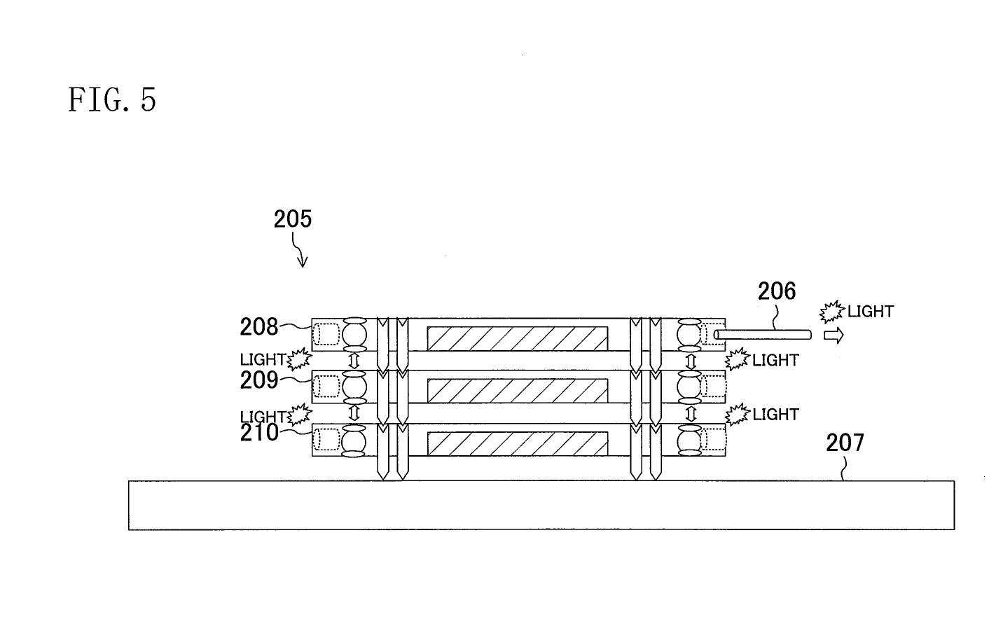

FIGS. 4 and 5 show schematic configuration of an integrated circuit package for realizing optical transmission as a second embodiment.

In FIG. 4, a symbol 201 represents a silicon chip on which a semiconductor integrated circuit is mounted. Symbols 202 represent light emitting/receiving units mounted in a periphery of the package. Symbols 203 represent light sockets for introducing light between the light emitting/receiving units and optical fibers. Symbols 204 represent power source/GND portions that are electrically connected to electric members in the package and that can be electrically connected to members outside of the package. Each of the power source/GND portions 204 has a metal pin structure on a lower portion thereof, and a metal socket structure on its upper portion.

In FIG. 5, a symbol 205 represents an apparatus having three packages 208, 209 and 210 having the same physical shapes and shown in FIG. 4. The three packages 208, 209 and 210 are connected to one another in the vertical direction. A symbol 206 represents an optical fiber that is mounted on a light socket of a certain package and that realizes optical transmission with a package located away from the packages 208, 209 and 210. A symbol 207 represents a system board (mother board) that is electrically connected to the power source/GND portion of the lowermost package 210.

The plurality of mounted optical packages each having the basic configuration shown in FIG. 4 are spatially bonded to one another at locations where the light emitting/receiving units 202 are vertically opposed to each other. With this, optical transmission is realized between a plurality of LSIs utilizing a light signal that can be recognized as a multilevel signal level in which light pulse or level by extremely faint light quantity is taken into account. In order to provide power supply, the lowermost package 210 is electrically connected to a power source/GND of the system board 207, and the upper packages 208 and 209 are electrically connected to power source/GND portions that are placed at physically the same positions. With this configuration, optical connection utilizing the shortest free space of a plurality of LSIs is carried out.

Symbols 204 represent power source/GND portions that are electrically connected to electric members in the package and that can be electrically connected to members outside of the package. Each of the power source/GND portions 204 includes a metal pin structure at its lower portion and a metal socket structure at its upper portion. A soldering ball may be mounted as a metal contact portion, or a metal surface may be mounted.

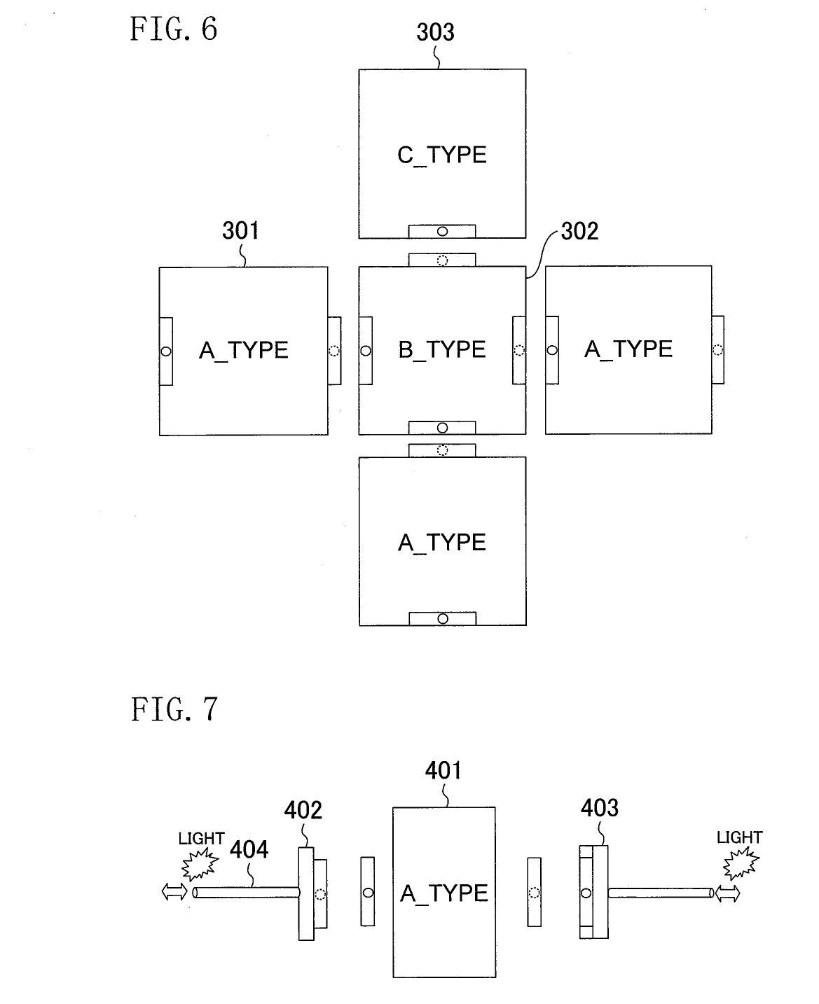

FIG. 6 is a plan view of a plurality of layouts of integrated circuit packages having tetragonal upper surfaces for realizing the optical transmission as a development of the first embodiment.

In FIG. 6, each of the optical packages having the tetragonal outside shape has light emitting/receiving units at opposed portions of its outer periphery. The optical package has such a basic shape that the optical package has a convex portion and a concave portion on its outer periphery, and the light emitting unit and the light receiving unit are mounted on the convex portion and the concave portion. The convex portion and the concave portion can physically be bonded to each other. At that time, they are bonded such that the light emitting unit and the light receiving unit of the two optical packages are opposed to each other. A symbol 301 represents a configuration (A type) provided at its opposed two sides of its outer periphery with a convex portion and a concave portion. A symbol 302 represents a configuration (B type) provided at its intersecting two sides of its outer periphery with a convex portion and a concave portion. A symbol 303 represents a configuration (C type) provided at its only one side of its outer periphery with a concave portion. A position and a structure of the power source/GND portion that makes it possible to electrically connect the packages and outside with each other are not especially limited.

According to the configuration shown in FIG. 6, the light emitting/receiving units provided on the convex portion and the concave portion of the outer periphery of the mounted package having the basic configuration are spatially bonded to each other at a location where they are opposed to each other in the vertical direction. With this, this configuration has such a feature that the optical transmission between a plurality of LSIs can be realized. In order to provide power supply, any suitable power source/GND metal contacts (not shown in the drawing) are provided on a lower surface of the package, and these metal contacts are electrically connected to the power source/GND electrodes of the system board. With this configuration, by combining, arranging and bonding outer peripheral optical contacts of the convex portion and the concave portion to each other, it is possible to mount the plurality of function LSIs within a smallest space.

With this configuration, concerning the arranging method of the outer peripheries of the convex portion and the concave portion, a plurality of combination arrangements can be made, and a plurality of convex portions and concave portions can be arranged on one side.

FIG. 7 shows a system connection of an optical package using optical fiber sockets having the same shapes as those of the convex portion and the concave portion mounted on the optical package as a development of the embodiment described in FIG. 6.

In FIG. 7, a symbol 401 represents an optical package having a convex portion and a concave portion on its opposed two sides of its outer periphery. A symbol 402 represents an optical fiber socket having the same outside shape of the concave portion as that of the optical package to which an optical fiber 404 is mounted as an optical transmission channel. A symbol 403 represents an optical fiber socket having the same outside shape of the convex portion as that of the optical package to which another optical fiber is mounted as an optical transmission channel.

The convex portion and the concave portion can physically be bonded to each other in the explanation of FIG. 6. Therefore, the optical fiber sockets 402 and 403 and the optical package 401 are bonded such that the light emitting unit and the light receiving unit are opposed to each other. The symbol 401 represents the optical package (A type) having the convex portion and the concave portion at the opposed two sides of its outer periphery, and packages that are placed at separated positions can be optically connected to each other through the optical fiber sockets 402 and 403 having two kinds of convex portions and concave portions.

In FIG. 7, a structure of a mating member sandwiched between optical fibers of the two kinds of optical fiber sockets 402 and 403 is not especially limited, the same optical fiber socket may be mounted, or the mating member may be connected to an optical module mounted using another structure.

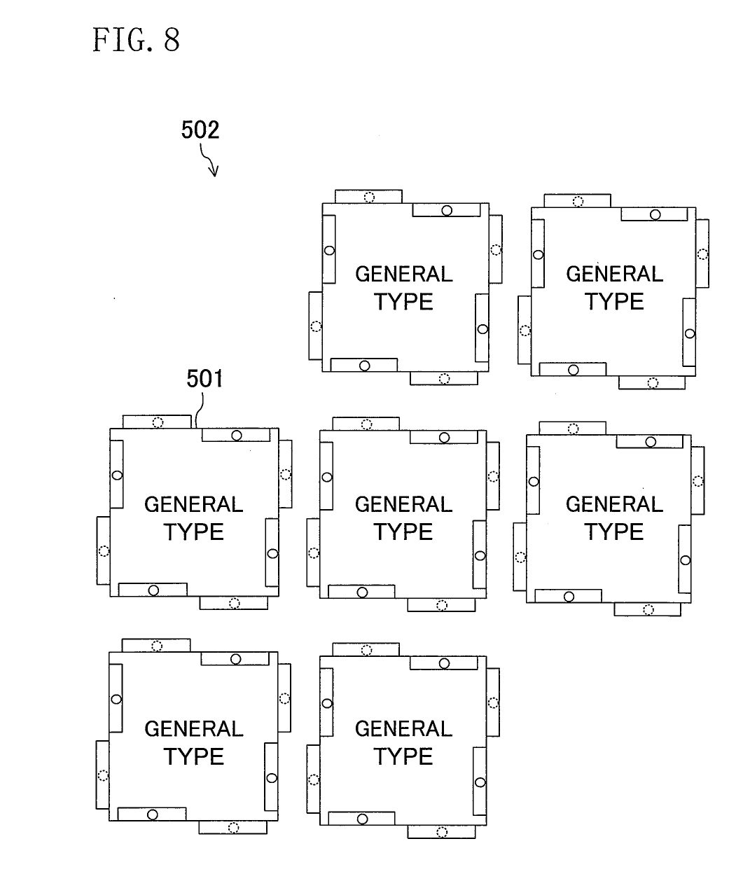

In FIG. 8, each of optical packages has a tetragonal outside shape. Light emitting/receiving units are provided at opposed portions of an outer periphery of the optical package. The optical package has such a basic shape that the outer periphery has a convex portion and a concave portion on its outer periphery, and the light emitting unit and the light receiving unit are mounted on the convex portion and the concave portion. The convex portion and the concave portion can physically be bonded to each other. At that time, they are bonded such that the light emitting unit and the light receiving unit of the two optical packages are opposed to each other.

In FIG. 8, a plurality of general-purpose packages 501 having physical structures in which the convex portion and the concave portion are arranged in the same manner with respect to the four sides of the package are arranged and connected to each other two-dimensionally. Here, light emitting/receiving units are provided in the convex portions and the concave portions of the outer periphery of the package mounted on four sides of the package are spatially bonded to each other by the basic configuration of the general-purpose package 501 at locations where the light emitting/receiving units are opposed in the vertical direction. The optical transmission between the plurality of LSIs can be realized by a system connection 502 by the plurality of packages, and physical shape is a symmetric with respect to a point through which the physical shape is rotated 90° relative to its barycenter. Therefore, two opposed sides of each of the plurality of packages can freely be bonded and arranged.

In order to provide power supply, any suitable power source/GND metal contacts (not shown in the drawing) are provided on a lower surface of the package, and these metal contacts are electrically connected to the power source/GND electrodes of the system board.

In addition to the light emitting unit and the light receiving unit of physical bonded portions, the convex portion and the concave portion can have such a structure that power source/GND electrodes (not shown in the drawing) are mounted, and the power source/GND electrodes are electrically connected in a cascade manner between a plurality of packages.

With this configuration, by combining and freely arranging and bonding the outer periphery optical contacts of the convex portion and the concave portion, it is possible to mount a plurality of function LSIs in a smallest space.

The arranging method of the outer periphery of the convex portion and the concave portion by this configuration has such a feature that the method has a symmetric structure with respect to a point when rotating 90°. A shape thereof is not limited, and the number of convex portions and concave portions to be arranged on one side may be two or more.

As an embodiment, a position and a structure of the power source/GND portion that makes it possible to electrically connect the package and the outside are not especially limited.

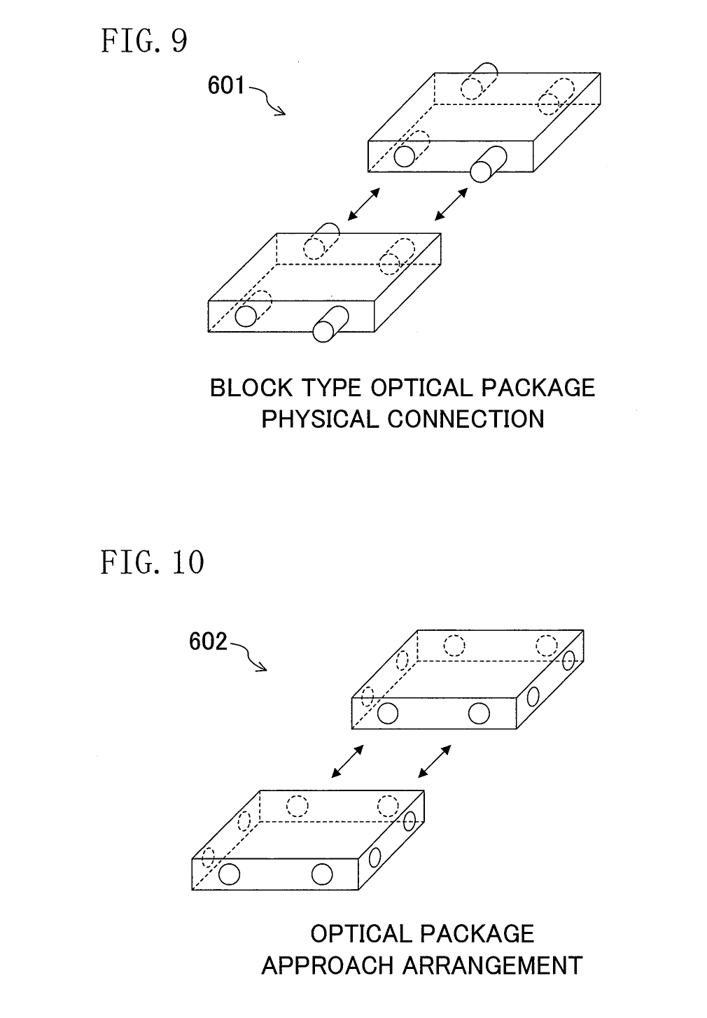

FIGS. 9 and 10 are perspective views when a plurality of general-purpose packages are three-dimensionally arranged and connected to each other such that the convex portion and the concave portion are arranged by a physical structure of concentric pins and sockets with respect to two sides of a side surface of the package.

FIG. 9 shows a block type optical package physical connection 601. In this connection, light emitting/receiving units provided on a pin and in a socket that are concentric with each other corresponding to the convex portion and the concave portion of an outer periphery of a package mounted on two sides of another package by the basic configuration are physically bonded at a location where the units are opposed to the mount surface horizontally. With this, it is possible to realize the optical transmission between a plurality of LSIs, and it is possible to freely bond and arrange two opposed sides of the plurality of packages.

In an optical package approach arrangement 602 shown in FIG. 10, a convex portion and a concave portion of an outer periphery of a package mounted on two sides of the package are not provided by the basic configuration, and a light emitting/receiving unit is embedded in a side surface of the package. In this configuration, the packages are bonded spatially within a short distance at a location where the package is opposed to the mount surface horizontally. With this, it is possible to realize the optical transmission between a plurality of LSIs, and it is possible to freely bond and arrange two opposed sides of the plurality of packages.

In order to provide power supply, any suitable power source/GND metal contacts (not shown in the drawing) are provided on a lower surface of the package, and this metal contacts are electrically connected to the power source/GND electrodes of the system board.

In addition to the light emitting unit and the light receiving unit of physical bonded portions, the convex portion and the concave portion can have such a structure that a power source/GND electrodes (not shown in the drawing) are mounted, and the power source/GND electrodes are electrically connected in a cascade manner between a plurality of packages.

If a configuration in which a light emitting/receiving unit is embedded in a side surface of a package is employed, a plurality of function LSIs can be mounted in a smallest space by combining and freely arranging and bonding outer periphery optical contacts.

When the light emitting/receiving unit is embedded in the side surface of the package in accordance with this configuration, the arranging method of the outer periphery has such a feature that it has a symmetric structure with respect to a point when rotating 90° by 90°, the embedding shape thereof is not limited, and the number of light emitting/receiving units convex portions and concave portions to be arranged on one side can be two or more.

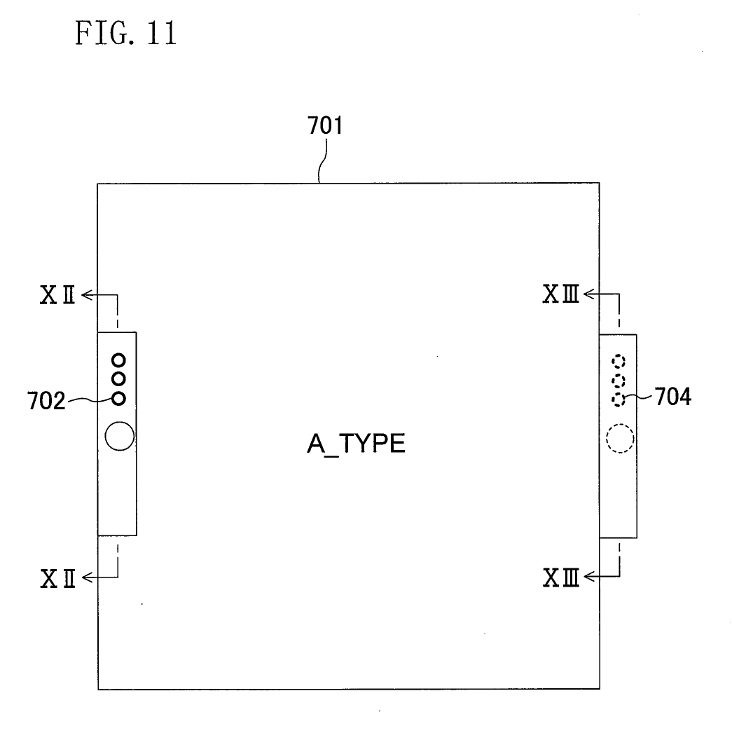

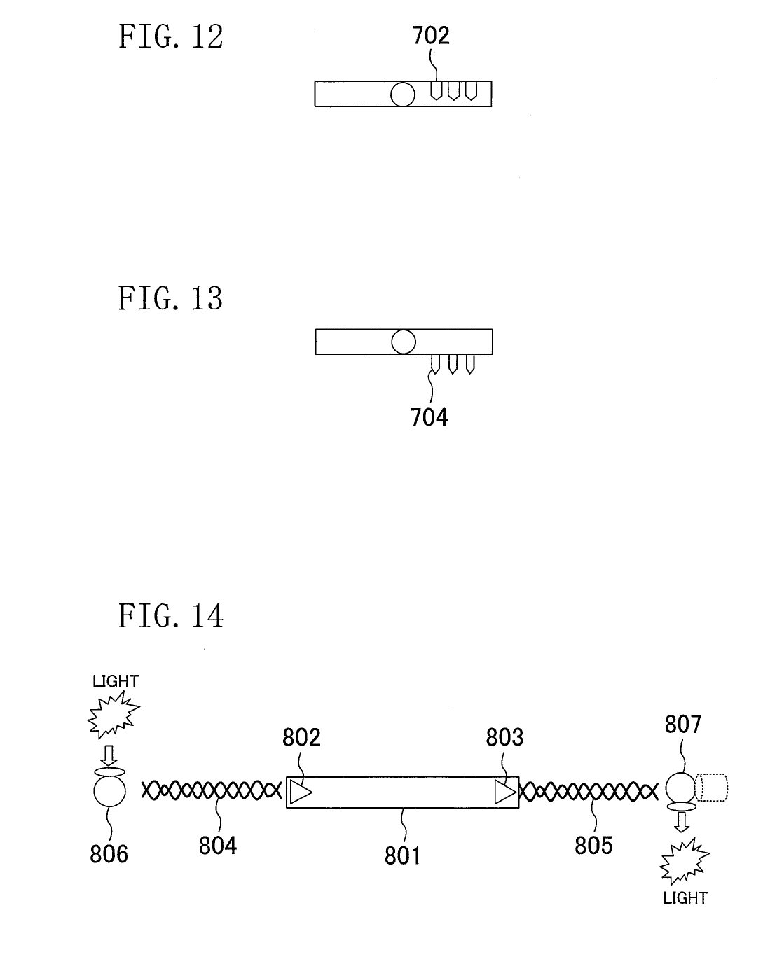

FIGS. 11 to 13 show embodiments in which transmission of a present electric signal by an approach of an integrated circuit package having a tetragonal upper surface is simultaneously realized for realizing the optical transmission as a development of the first embodiment.

In FIGS. 11 to 13, light emitting/receiving units are provided on opposed portions of an outer periphery in an optical package having a tetragonal outside shape, it has such a basic shape that its outer periphery has a convex portion and a concave portion, a light emitting unit and a light receiving unit are mounted on the convex portion and the concave portion, and an electric contact portion for realizing connection of an electric signal is provided. The convex portion and the concave portion can physically be bonded to each other. At that time, they are bonded to each other such that the light emitting units and the light receiving units of the two optical packages are opposed to each other, and the electric contact portions come into contact in a form of pins and sockets, and the optical packages are energized. A symbol 701 represents the optical package (A type) having a convex portion and a concave portion at its two opposed sides of its outer periphery. A symbol 702 represents a structure of electrodes (metal sockets) that are arranged in the concave portion for realizing electrical connection. A symbol 704 represents a structure of electrodes (metal pins) that are arranged on the convex portion for realizing electrical connection.

In order to provide power supply of the configuration of the optical package 701, any suitable power source/GND metal contacts (not shown in the drawing) are provided on a lower surface of the package, and these metal contacts are electrically connected to the power source/GND electrodes of the system board.

In addition to the light emitting unit, the light receiving unit and the electric signal connecting portion of physical bonded portions, the convex portion and the concave portion can have such a structure that power source/GND electrodes (not shown in the drawing) are mounted, and the power source/GND electrodes are electrically connected in a cascade manner between a plurality of packages.

With this configuration, by combining and freely arranging and bonding the outer peripheral optical connections of the convex portion and the concave portion and the electric signal connection with each other, a plurality of function LSIs can be mounted in a smallest space.

The arranging method of the outer peripheries of the convex portion and the concave portion of this configuration has such a feature that it has a symmetric structure with respect to a point when rotating 90°, a shape thereof is not limited, and the number of convex portions and concave portions to be arranged in on one side may be two or more.

A position and a structure of the power source/GND portion that makes it possible to electrically connect the package and the outside are not especially limited.

FIG. 14 shows a mounting example of optical transmission function parts in an integrated circuit package of the present invention. In FIG. 14, a symbol 801 represents a silicon chip on which a semiconductor integrated circuit is mounted. A symbol 802 represents an electrical receiving circuit mounted on the silicon chip. A symbol 803 represents an electrical transmission circuit mounted on the silicon chip. A symbol 806 represents a light-electricity converting light receiving element arranged near a bonded portion outside of the package. A symbol 807 represents an electricity-light converting light emitting element arranged near the bonded portion outside of the package. Symbols 804 and 805 represent electric transmission channels (sending/receiving LVDS) in the package for connecting the electrical sending/receiving circuits 802 and 803 with the light-electricity converting elements 806 and 807. The light emitting unit and the light receiving unit that realize the optical transmission by a short-distance bonding basically include the light receiving element 806, its driver, the light emitting element 807, its receiver, and an optical part for changing an optical path.

A mounting style of the optical transmission function parts shown in FIG. 14 is not especially limited. All of the parts are mounted on the semiconductor integrated circuit in some cases. Concerning the light emitting element, an LED and a semiconductor laser are effective. A connecting method for these and an internal semiconductor integrated circuit is not limited.

### INDUSTRIAL APPLICABILITY

As described above, the present invention is effective as a mounting style of a signal transmission by a light signal between semiconductor chips such as LSIs.

### DESCRIPTION OF REFERENCE CHARACTERS

101 Silicon Chip on which Semiconductor Integrated Circuit is Mounted
102 Light Receiving Unit
103 Light Emitting Unit
104 Light Socket
105 Power Source/GND Portion
106 Mount Body or Lid
107 Apparatus in which Three Optical Packages are Connected to One Another
108, 109, 110 Optical Package (Integrated Circuit Package)
111, 112 Optical Fiber
113 System Board (Motherboard)
201 Silicon Chip on which Semiconductor Integrated Circuit is Mounted
202 Light Emitting/Receiving Unit
203 Light Socket
204 Power Source/GND Portion
205 Apparatus in which Three Optical Packages are Connected to One Another
206 Optical Fiber
207 System Board (Motherboard)
208, 209, 210 Optical Package (Integrated Circuit Package)
301 Package Having a Convex Portion and a Concave Portion Provided on Two Opposed Sides of its Outer Periphery
302 Package whose Intersecting Two Sides of its Outer Periphery are Convex and Concave, Respectively
303 Package Having Only One Concave Side of its Outer Periphery
401 Package Having a Convex Portion and a Concave Portion Provided on Two Opposed Sides of its Outer Periphery
402, 403 Optical Fiber Socket
404 Optical Fiber
501 General-Purpose Package
502 System Connection Having a Plurality of Packages
601 Block Type Optical Package Physical Connection
602 Optical Package Approach Arrangement
701 Package Having a Convex Portion and a Concave Portion Provided on Two Opposed Sides of its Outer Periphery
702 Electrode Arranged in a Concave Portion for Realizing Electrical Connection
704 Electrode Arranged on a Convex Portion for Realizing Electrical Connection
801 Silicon Chip on which Semiconductor Integrated Circuit is Mounted
802 Electrical Receiving Circuit
803 Electrical Transmission Circuit
804, 805 Electric Transmission Channel in Package
806, 807 Light-Electricity Converting Element

1. An integrated circuit package on which a semiconductor integrated circuit is mounted,
wherein
a portion of the package or a portion of an outer periphery thereof includes a light emitting unit and a light receiving unit,
the package has such a basic shape that its outer periphery includes a convex portion and a concave portion,
the light emitting unit and the light receiving unit are mounted on the convex portion and the concave portion, and
the convex portion can physically be bonded to a concave portion of another package, the concave portion can physically be bonded to a convex portion of another package and at that time, light emitting units and light receiving units of the two integrated circuit packages are bonded to each other such that they are opposed to each other.

2. The integrated circuit package of claim 1, wherein
the convex portion and the concave portion further include such a structure that power source/GND electrodes are mounted on a physical bonded portion in addition to the light emitting unit and the light receiving unit, and the power source/GND electrodes are connected between a plurality of integrated circuit packages in a cascade manner.

3. The integrated circuit package of claim 1, wherein
the convex portion and the concave portion further include such a structure that an input/output electrode of an electric signal is mounted on a physical bonded portion in addition to the light emitting unit and the light receiving unit, and the electric signal is connected between a plurality of integrated circuit packages.

4. The integrated circuit package of claim 1, wherein
it is possible to employ such a configuration that a mother board and the integrated circuit package are electrically connected to each other only through a power source/GND.

5. The integrated circuit package of claim 1, wherein
when an upper surface has a tetragonal shape, the convex and concave portions can be connected in four directions of an outer periphery of the upper surface.

6. The integrated circuit package of claim 1, wherein
when an upper surface has a tetragonal shape, light receiving unit and a light emitting unit are provided on the upper surface and a lower surface, and when a plurality of integrated circuit packages are piled on one another, the convex and concave portions can be connected in four mounting directions at locations where the light receiving unit and the light emitting unit are opposed to each other.

7. The integrated circuit package of claim 1, further comprising:
a structure that a plurality of signal electrodes are arranged on a back surface of the package for realizing conventional metal transmission.

8. The integrated circuit package of claim 1, wherein
to realize high speed optical transmission, the light emitting unit and the light receiving unit include a light receiving element, a driver thereof, a light emitting element, a receiver thereof, and an optical part for changing an optical path.
